(19) United States
(12) Patent Application Publication
(10) Pub. No.: US 2005/0139945 A1
(43) Pub. Date: Jun. 30, 2005

(54) Image sensor and method for fabricating the same

(75) Inventor: Keun Hyuk Lim, Eumsung-gun (KR)

Correspondence Address: THE LAW OFFICES OF ANDREW D. FORTNEY, PH.D., P.C., 7257 N. MAPLE AVENUE, BLDG. D, 3107, FRESNO, CA, 93720, US

(73) Assignee: DongbuAnam Semiconductor Inc.

(21) Appl. No.: 11/026,903

(22) Filed: Dec. 29, 2004

(30) Foreign Application Priority Data
Dec. 31, 2003 (KR) 10-2003-0101699

(51) Int. Cl. H01L 21/00; H01L 31/0232; H01L 31/00

(52) U.S. Cl. 257/432; 438/70; 257/440

(57) ABSTRACT

Image sensor and method for fabricating the same are disclosed, wherein, instead of a traditional microlens array over a color filter array, a microlens pattern is arranged under the color filter array, which can permit shortening a total travel distance of a converged light to the photodiode, improve intensity and focus of the light finally reaching the photodiode array, and improve a low luminance performance of the image sensor. The minimized travel distance of the converged light, which optimizes intensity and focus of the light reaching the photodiode array, permits significantly improving an image quality reproduced by the image sensor.

### CROSS-REFERENCE TO RELATED APPLICATIONS

This application claims the benefit of Korean Application No. P2003-101699 filed on Dec. 31, 2003, which is hereby incorporated by reference as if fully set forth herein.

### BACKGROUND OF THE INVENTION

1. Field of the Invention

The present invention relates to image sensors, and more particularly, to an image sensor, in which, instead of a traditional microlens array over the color filter array, a microlens pattern is arranged newly under a color filter array, which can substitute a function of the microlens array, to enable to shorten a total distance of travel of a converged light finally reaching to the photodiode, that improves intensity and focus of the light finally reaching to the photodiode array, to improve a low luminance performance of the image sensor completed finally, significantly; and a method for fabricating the same.

2. Discussion of the Related Art

Recently, as electric and electronic technologies are developed rapidly, a variety of electronic products having image sensor technologies applied thereto, such as video cameras, digital cameras, PCs with built-in miniature cameras, cellular phones with built-in miniature cameras, and so on, are developed, and spread widely.

Traditionally, though Charge Coupled Devices (CCD) have been used as the image sensors, because the CCD has many disadvantages in that a high driving voltage and an additional separate supporting circuit may be required, a process cost is high, and so on, presently it is a trend that use of the CCD is reduced, drastically.

Recently, as image sensors that can replace the CCD, Complementary Metal Oxide Semiconductor (CMOS) image sensors attract much interest. Different from the present CCD, because the CMOS image sensors are fabricated based on CMOS circuit technologies, the CMOS image sensors have advantages in that low voltage driving is possible, no additional supporting circuit is required, the process cost is low, and so on.

Referring to FIG. 1, such a related art image sensor, for an example, the CMOS image sensor, is provided with a microlens array 7 for converging a light from an exterior lens 100, a color filter array 6 for converting the light converged by the microlens array 7 into a color light, a planarizing layer 5 on the color filter array 6 for planarizing a base of the microlens array 7 to induce uniform light transmission, a light transmission layer 4 for transmission of the light converted into the color light at the color filter layer 7 toward a photodiode array 3, and the photodiode array 3 on an active region of a semiconductor substrate 1 defined by an active cell isolation layer 2, for receiving the light passed through the light transmission layer 4, to produce, and store photo charges.

In this instance, by using its own curvature, the microlens array 7 passes a light incident on a point p1 in a straight line, and refracts lights incident on points p2, and p3 at an angle, so that all the lights passed through the exterior lens 100 are focused on the photodiode array 3.

As described before, in the related art image sensor, the light converged by the microlens array 7 is provided to the photodiode array 3 through the color filter array 6, the light transmission layer 4, and so on. That is, there is a substantial distance for the light converged at the microlens array 7 and reaching to the photodiode array 3.

Thus, if there is a substantial distance between the microlens array 7 and the photodiode array 3, an intensity and a focus of the light incident on the photodiode array 3 can not but be distorted in proportion to the distance, and as a result of this, a low luminance performance of the image sensor can not but be dropped, significantly.

Of course, if such a drop of low luminance performance of the image sensor is left as it is without taking any proper countermeasure, the image finally formed by the image sensor can not but have a substantially low quality.

### SUMMARY OF THE INVENTION

Accordingly, the present invention is directed to an image sensor and a method for fabricating the same that substantially obviates one or more problems due to limitations and disadvantages of the related art.

An object of the present invention is to provide an image sensor having a microlens pattern under a color filter array, for minimizing a total distance of travel by focused light to a photodiode array.

Another object of the present invention is to provide an image sensor that minimizes the distance-proportional distortion in light intensity and focus to the photodiode array, and that may have improved low luminance performance.

Another object of the present invention is to provide an image sensor having a microlens pattern under a color filter array, that may provide some protection for the microlens array.

A further object of the present invention is to provide an image sensor having a significantly improved reproduced image quality.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of making an image sensor includes the steps of forming a photodiode array in an active region of a semiconductor substrate defined by an active cell isolation film; forming a light transmission layer on the photodiode array; forming a microlens pattern on the light transmission layer, the microlens pattern being adapted to converge an external light; and forming a color filter array over the microlens pattern.

In another aspect of the present invention, an image sensor includes a color filter array for converting an external light into a color light; a microlens pattern under the color filter array for converging the color light passing through the color filter array; a photodiode array in an active region of a semiconductor substrate for receiving the light converged at the microlens pattern, adapted to produce and store photo charges; and a light transmission layer over the photodiode array for supporting the microlens pattern and the color filter array, and transmitting the light converged at the microlens patterns toward the photodiode array.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 illustrates a section of an example of a conventional image senor;

FIG. 2 illustrates a section of an example of an image senor in accordance with a preferred embodiment of the present invention; and

FIGS. 3A˜3E illustrate sections showing the steps of a method for fabricating an image sensor in accordance with a preferred embodiment of the present invention.

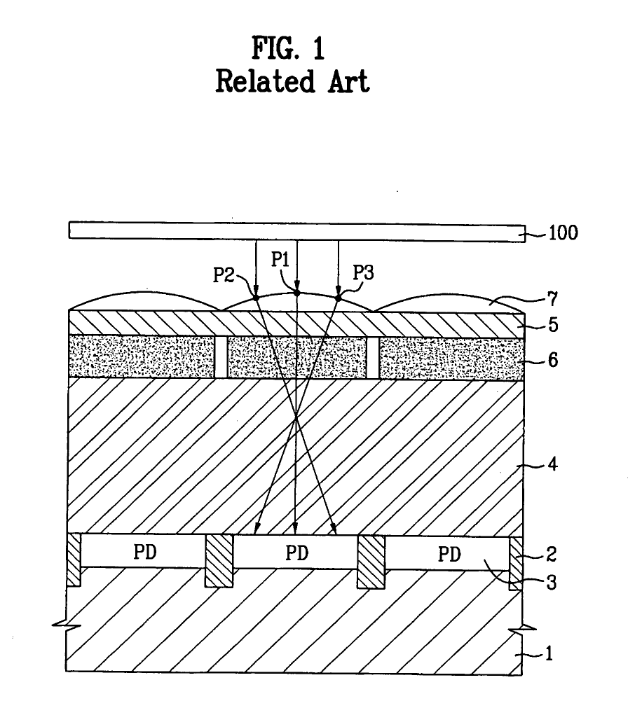

### DETAILED DESCRIPTION OF TH INVENTION

Reference will now be made in detail to the preferred embodiments of the present invention, examples of which are illustrated in the accompanying drawings. Wherever possible, the same reference numbers will be used throughout the drawings to refer to the same or like parts.

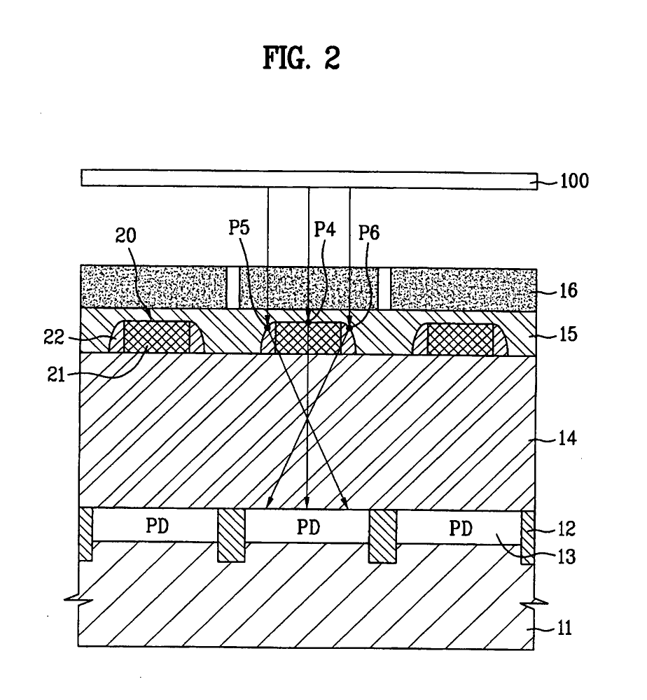

Referring to FIG. 2, the image sensor, for an example, a CMOS image sensor, includes a color filter array 16 for converting a light from an exterior lens 100 into a color light, a light transmission layer 14 for transmission of the light converted into the color light at the color filter layer 16 toward a photodiode array 13, and the photodiode array 13 on a semiconductor substrate 11 at an active region defined by an active cell isolation layer 12, for receiving the light passed through the light transmission layer 14, to produce, and store photo charges.

The light transmission layer 14 having a PMD insulating film, metal wiring, interlayer insulating film, and so on, is over the semiconductor substrate 11 to cover the photodiode array 13 and support the color filter array 16. In this case, there is a planarizing layer 15 on the light transmission layer 14 for planarizing a base of the color filter array 16 to induce uniform transmission of the light.

As shown, in the image sensor of the present invention, instead of eliminating the traditional microlens array from a location on or over the color filter array 16, a microlens pattern 20 is arranged under the color filter array 16 for effective convergence of the light passed through the color filter array 16 in substitution of a function of the related art microlens array.

In this case, preferably, the microlens pattern 20 includes a first lens pattern 21 comprising an oxide (e.g., a conventional silicon dioxide) for passing a light from the color filter array 16 toward the photodiode array 13 in a substantially straight line or direction (e.g., substantially normal to the planar upper surface of the photodiode 13), and a second lens pattern 22 of nitride (for example, SiN) on sidewalls of the first lens pattern 21 so as to cover the sides in a rounded shape, for refracting the light passed through the color filter array 16 toward the photodiode array 13.

Preferably, the first lens pattern 21 has a thickness of 11,000 Å˜14,000 Å, and the second lens pattern 22 has a thickness of 6,000 Å˜8,000 Å.

Of course, as is known widely, the nitride film has a refractive index greater than the oxide film. Therefore, as shown in the drawing, if the microlens pattern 20 has a structure in which the second lens pattern 22 of nitride covers sidewalls of the first lens pattern 21 of oxide in a rounded shape, the light incident on a point p4 passes the first lens pattern 21 in a straight line, and the light incident on points p5 and p6 refract at an angle, and pass through the second lens pattern 22 such that all the light passing through the exterior lens 100 can be converged toward the photodiode array 13 without problem, at the end.

In summary, by newly arranging the microlens pattern 20 under the color filter array 16, for performing essentially the same function as a traditional microlens, a total distance of travel of a focused light to the photodiode array 13 can be minimized.

The microlens array, which converges a light, over the color filter array in the related art can not but transmit a converged light to the photodiode array through the color filter array, the light transmission layer, and so on, and as a result of which intensity and a focus of the light finally reaching to the photodiode array can not but be distorted in proportion to the distance, to drop a low luminance performance of the image sensor completed finally, substantially at the end.

However, the microlens pattern 20, which converges a light, under the color filter array 16 in the present invention enables the converged light to transmit toward the photodiode array 13 naturally after passing through a short distance of the light transmission layer 14, such that the intensity and focus of the light reaching to the photodiode array 13 finally can be maintained to be at an optimum state, to improve the low luminance performance of the image sensor completed finally, at the end.

When the distance of travel of the converged light is minimized, to optimize the intensity and focus of the light reaching to the photodiode array 13, a quality of the image reproduced finally by the image sensor can be improved, significantly.

A method for fabricating the foregoing image sensor will be described in detail.

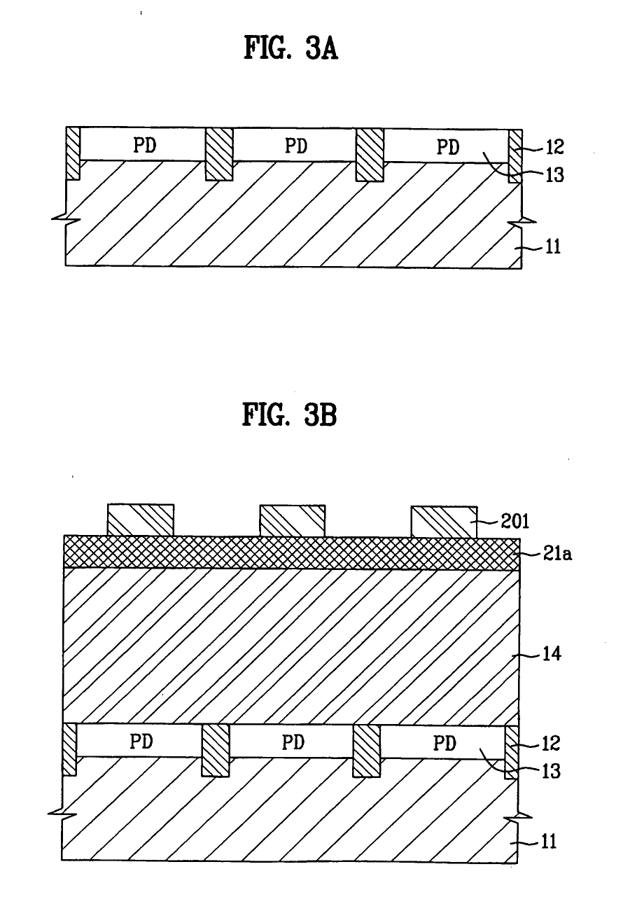

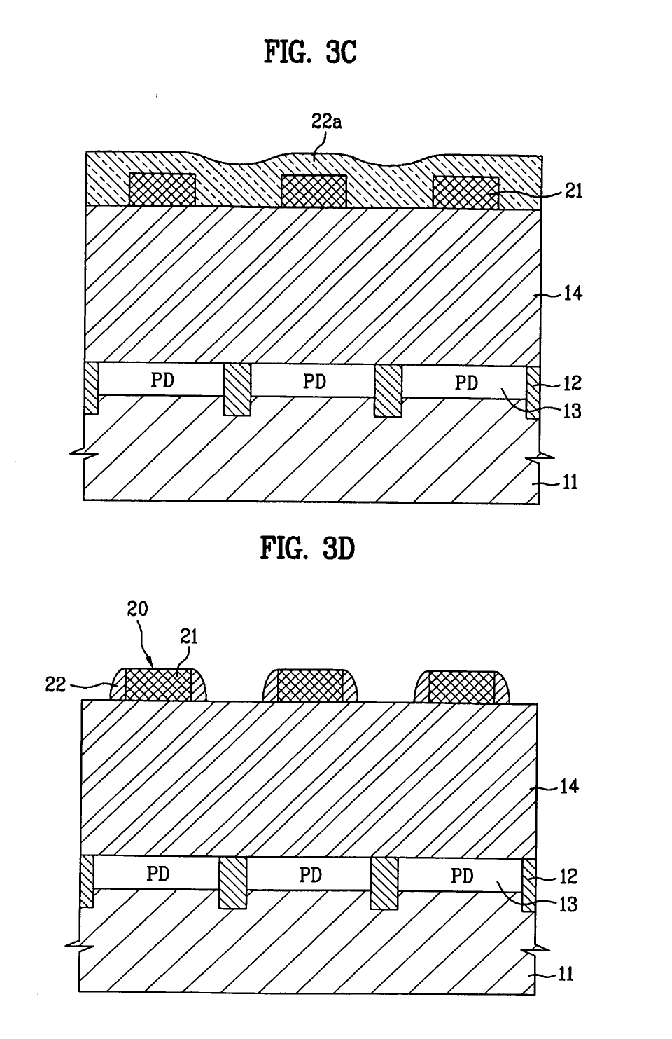

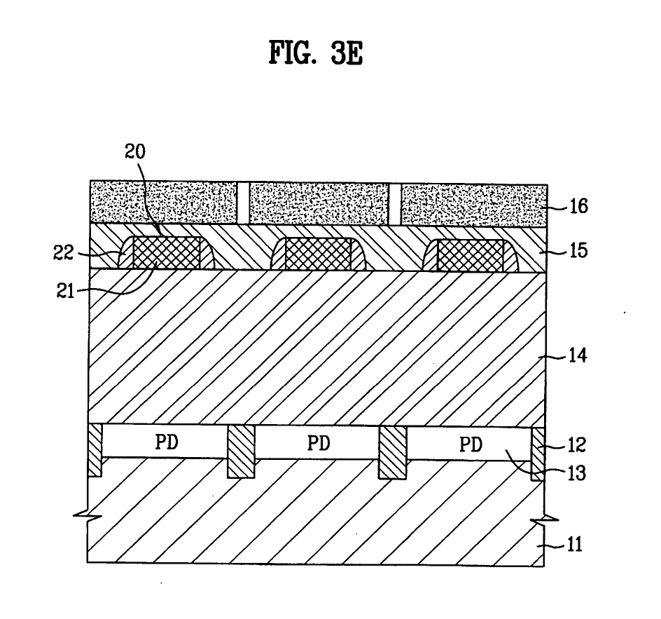

Referring to FIG. 3A, an STI process (Shallow Trench Isolation process), or an LOCOS process (LOCal Oxidation of Silicon process), or the like is performed, to form an active cell isolation film 12 in the semiconductor substrate to define an active region of a semiconductor substrate 11. In this case, a P-type epitaxial layer (not shown) may be formed on the semiconductor substrate 11, such as a heavily doped P⁺⁺ type single crystal silicon substrate depending on a situation for increasing a size (depth) of a depletion region.

Then, ions are injected to define a P-type impurity layer, an N-type impurity layer, and so on in the semiconductor substrate 11 at the active region, to form a photodiode array 13 for producing, accumulating photo charges.

Next, referring to FIG. 3B, deposition, etching, and the like are repeated, to form a light transmission layer 14 having, for an example, a PMD insulating film, metal wirings, an interlayer insulating film, and so on on the semiconductor substrate 11 inclusive of the photodiode array 13.

Of course, a structure, and a fabricating sequence of the light transmission layer 14 can be varied with situations.

Chemical vapor deposition is performed, to form an oxide film layer 21a on the light transmission layer 14 to a thickness of, for an example, 11000 Å˜14000 Å, and a photoresist pattern 201 is formed on the oxide film layer 21a for defining a first lens pattern to be formed, later.

Referring to FIG. 3C, an exposure process and a development process, and the like are performed based on the photoresist pattern 201, to form first lens patterns 21 spaced from one another on the light transmission layer 14.

Then, referring to FIG. 3D, after a chemical vapor deposition is performed, to form a nitride film layer 22a on the light transmission layer 14 inclusive of the first lens pattern 21, dry etching having an anisotropic characteristic, for an example, reactive ion etching, is performed targeting at the nitride film layer 22a, to form second lens patterns 22 at opposite sides of the first lens pattern 21 to a thickness of, for an example, 6000 Å˜8000 Å.

Upon finishing above process, the microlens pattern 20 including the first lens pattern 21 of oxide, and the second lens pattern 22 of nitride covering the opposite sides of the first lens pattern 21 in rounded shapes is formed on the light transmission layer 14.

Upon finishing fabrication of the microlens pattern 20, depending on a situation, an ozone-TEOS (Tetra Ortho Silicate Glass) process, an atmospheric pressure chemical vapor deposition process, a plasma chemical vapor deposition process, a high density plasma chemical vapor deposition process (HDP CVD process), or the like is performed selectively, to form a planarizing layer 15 on the light transmission layer 14 to cover the microlens pattern 20, and a chemical mechanical polishing process is performed, to polish the planarizing layer, smoothly.

Then, deposition, patterning, and so on are performed, to form a color filter array 16 on the planarizing layer 15, to finish fabrication of the image sensor intended to obtain from the present invention.

As has been described, instead of the traditional microlens array over the color filter array, the microlens pattern arranged newly under the color filter array, which can substitute a function of the microlens array, permits to shorten a total distance of travel of a converged light finally reaching to the photodiode, that improves intensity and focus of the light finally reaching to the photodiode array, to improve a low luminance performance of the image sensor completed finally, significantly.

The minimized travel distance of the converged light, which optimizes intensity and focus of the light finally reaching to the photodiode array, permits to improve a quality of the image reproduced by the image sensor, significantly.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. An image sensor comprising:
a color filter array for converting an external light into a color light;
a microlens pattern under the color filter array for converging the color light passing through the color filter array;
a photodiode array in an active region of a semiconductor substrate for receiving the light converged at the microlens pattern, adapted to produce and store photo charges;
a light transmission layer over the photodiode array for supporting the microlens pattern and the color filter array, and transmitting the light converged at the microlens patterns toward the photodiode array.

2. The image sensor as claimed in claim 1, wherein each microlens includes:
a first lens pattern for passing a light from the color filter array toward the photodiode array in a substantially straight line, and
a rounded lens portion on sidewalls of the first lens portion, configured to refract the color light passing through the color filter array toward the photodiode array.

3. The image sensor as claimed in claim 2, wherein the rounded lens portion has a refractive index relatively greater than the first lens pattern.

4. The image sensor as claimed in claim 2, wherein the first lens pattern comprises an oxide, and the rounded lens portion comprises a nitride.

5. The image sensor as claimed in claim 2, wherein the first lens pattern has a thickness of 11,000 Å˜14,000 Å, and the rounded lens portion has a thickness of 6000 Å˜8,000 Å.

6. A method for fabricating an image sensor comprising the steps of:
forming a photodiode array in an active region of a semiconductor substrate defined by an active cell isolation film;
forming a light transmission layer on the photodiode array;
forming a microlens pattern on the light transmission layer, the microlens pattern being adapted to converge an external light; and
forming a color filter array over the microlens pattern.

7. The method as claimed in claim 6, wherein the step of forming the microlens pattern includes the steps of:
depositing and patterning an oxide film on the light transmission layer to form a first lens pattern; and
depositing a nitride film on the light transmission layer to cover the first lens pattern, and etching the nitride film to form rounded shapes on sidewalls of the first lens pattern.
